(19) United States
(12) Patent Application Publication
(10) Pub. No.: US 2024/0121934 A1
(43) Pub. Date: Apr. 11, 2024

(54) MICROELECTRONIC DEVICE WITH STACKED TRANSISTORS

(71) Applicant: International Business Machines Corporation, Armonk, NY (US)

(72) Inventors: Jens Künzer, Boeblingen (DE); Tobias Werner, Weil Im Schoenbuch (DE); Iris Maria Leefken, Dettenhausen (DE); Gerhard Hellner, Boeblingen (DE)

(21) Appl. No.: 18/145,507

(22) Filed: Dec. 22, 2022

(30) Foreign Application Priority Data
Oct. 11, 2022 (GB) 2214943.9

(51) Int. Cl. H10B 10/00

(52) U.S. Cl. CPC H01L 27/1108

(57) ABSTRACT

A processor may form a first power line and a second power line. The processor may form a first memory cell with at least six transistors and a second memory cell with at least six transistors. The first pair of transistors of the first memory cell may be stacked vertically and connected at a common net. The common net may be arranged transverse to the first pair of transistors. The first pair of transistors may be configured to share the first power line. The second pair of transistors of the first memory cell may be stacked vertically and connected at a common net. The common net may be arranged transverse to the second pair of transistors. The second pair of transistors may be configured to share the second power line. The transistors of the first pair of transistors are configured to operate independently from the second pair of transistors.

### BACKGROUND

The present invention relates in general to data processing systems, and more particularly to a microelectronic device and a method of forming a microelectronic device.

When producing microelectronic devices, a number of process layers are formed on a substrate, each process layer incorporating a layout pattern. The layout patterns within the various layers establish component features and interconnections such that once the final process layer has been formed, a microelectronic device has been produced containing the required circuit components interconnected in the manner required to perform the functions of the microelectronic device.

Mostly, microelectronic devices include multiple adjacent layers which are deposited and structured one after the other. Power supply rails are provided to supply power to the cells of the microelectronic device. Cells of the microelectronic device may include static random access memory (SRAM) cells for storing data and logic cells for performing combinatorial logic functions, such as using NAND gates and NOR gates. Signal lines are provided for transmitting data, for example, the result of a Boolean operation or data (to be) stored in a cell (e.g., a SRAM cell). The cells of the microelectronic device include field effect transistors (FETs), each including a drain region, a source region, a channel region, and a gate region. Typically, the FETs are formed in the lowest layers of the microelectronic device. The layers comprising the signal lines and the power supply rails are provided in layers above the FETs.

### SUMMARY

Embodiments of the present disclosure include an apparatus. method, and system for a microelectronic device.

A processor may form a first power line. The processor may form a second power line. The processor may form a first memory cell with at least six transistors. The processor may form a second memory cell with at least six transistors. The first pair of transistors of the first memory cell may be stacked vertically and connected at a common net. The common net may be arranged transverse to the first pair of transistors. The first pair of transistors may be configured to share the first power line. The second pair of transistors of the first memory cell may be stacked vertically and connected at a common net. The common net may be arranged transverse to the second pair of transistors. The second pair of transistors may be configured to share the second power line. The transistors of the first pair of transistors are configured to operate independently from the second pair of transistors.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a circuit diagram of an SRAM memory cell comprising six transistors according to state of the art, in accordance with aspects of the present disclosure.

FIG. 2 depicts a circuit diagram of an example microelectronic device, in accordance with aspects of the present disclosure.

FIG. 3 depicts example schematics of memory cells in interleaving two rows sharing bitlines and wordlines, in accordance with aspects of the present disclosure.

FIG. 4 depicts an example of a physical structure of a microelectronic device, in accordance with aspects of the present disclosure.

FIG. 5 depicts an isometric view of an example physical structure of a single transistor of the microelectronic device according to an embodiment of the invention in an isometric view, in accordance with aspects of the present disclosure.

FIG. 6 depicts an isometric view of an example physical structure of a microelectronic device, in accordance with aspects of the present disclosure.

FIG. 7 depicts a cross-section view of an example microelectronic device, in accordance with aspects of the present disclosure.

FIG. 8 depicts an example of a microelectronic device with the two memory cells, in accordance with aspects of the present disclosure.

FIG. 9 depicts a cross-section of an example microelectronic device, in accordance with aspects of the present disclosure.

FIG. 10 depicts an example physical structure of the microelectronic device, in accordance with aspects of the present disclosure.

While the embodiments described herein are amenable to various modifications and alternative forms, specifics thereof have been shown by way of example in the drawings and will be described in detail. It should be understood, however, that the particular embodiments described are not to be taken in a limiting sense. On the contrary, the intention is to cover all modifications, equivalents, and alternatives falling within the spirit and scope of the disclosure.

### DETAILED DESCRIPTION

In the drawings, like elements are referred to with equal reference numerals. The drawings are merely schematic representations, not intended to portray specific parameters of the invention. Moreover, the drawings are intended to depict only some embodiments of the invention and therefore should not be considered as limiting the scope of the invention.

The illustrative embodiments described herein disclose a microelectronic device that may comprise a plurality of conducting layers. The microelectronic device may comprise a first memory cell with at least six transistors, a second memory cell with at least six transistors. A first pair of transistors of the first memory cell may be stacked vertically and connected at a common net. More particularly, the first pair of transistors of the first memory cell may be connected at a common net arranged transverse to the first pair of transistors. Each transistor of the first pair of transistors may be of the same type. The first pair of transistors may be configured to share a first common power line. A second pair of transistors of the first memory cell may be stacked vertically and connected at a common net. More particularly, the first pair of transistors of the first memory cell may be connected at a common net arranged transverse to the second pair of transistors. Each transistor of the second pair of transistors may be of the same type (e.g., referring to polarity and/or transistor types) and may be a different type than the first pair of transistors. The second pair of transistors may be configured to share a second common power line. The transistors of the first and second pair of transistors may be configured to operate independently from each other.

The illustrative embodiments are sometimes described herein using particular technologies, such technologies are for example only and should not be construed as limiting.

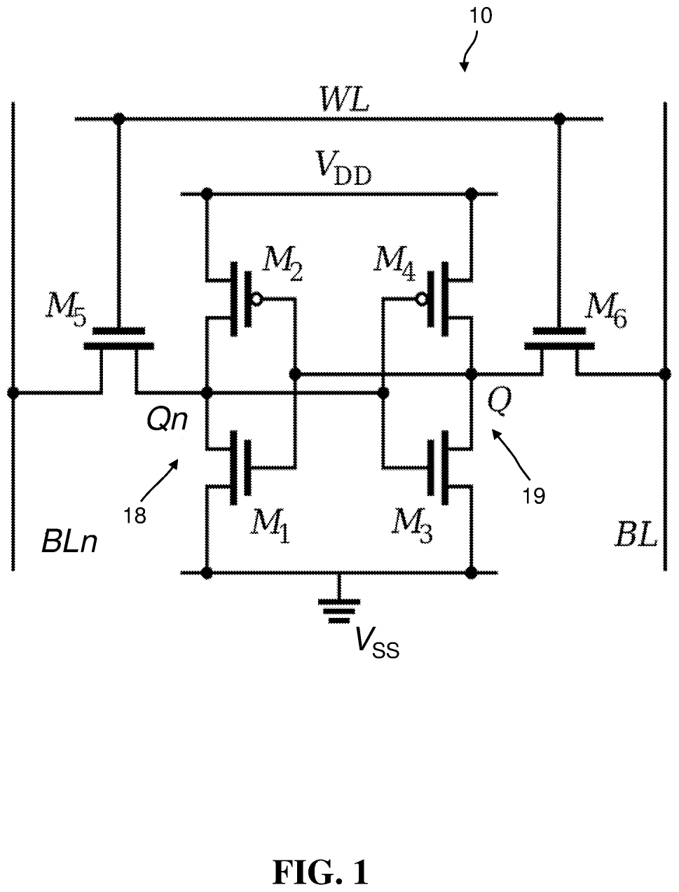

FIG. 1 depicts a circuit diagram of an SRAM memory cell 10 comprising six transistors referred to as M₁, M₂, M₃, M₄, M₅, M₆, respectively.

A first pair of transistors M₁, M₃ may be connected to a first power line Vₛₛ and a second pair of transistors M₂, M₄ may be connected to a second power line V_{dd}.

The memory cell 10 may comprise a first inverter 18 with a first transistor M₁ and a second transistor M₂ and a second inverter 19 with a first transistor M₃ and a second transistor M₄. The first inverter 18 and the second inverter 19 may be cross coupled. The first inverter 18 inverts a true signal Q and drives a complement signal Qn. In some embodiments, the second inverter 19 may invert a complement signal Qn and drive a true signal Q.

A gate of the transistor M₅ and a gate of the transistor M₆ may be connected to a wordline WL. A drain of the transistor M₅ may be connected to a complement bitline BLn and a drain of the transistor M₆ may be connected to a true bitline BL.

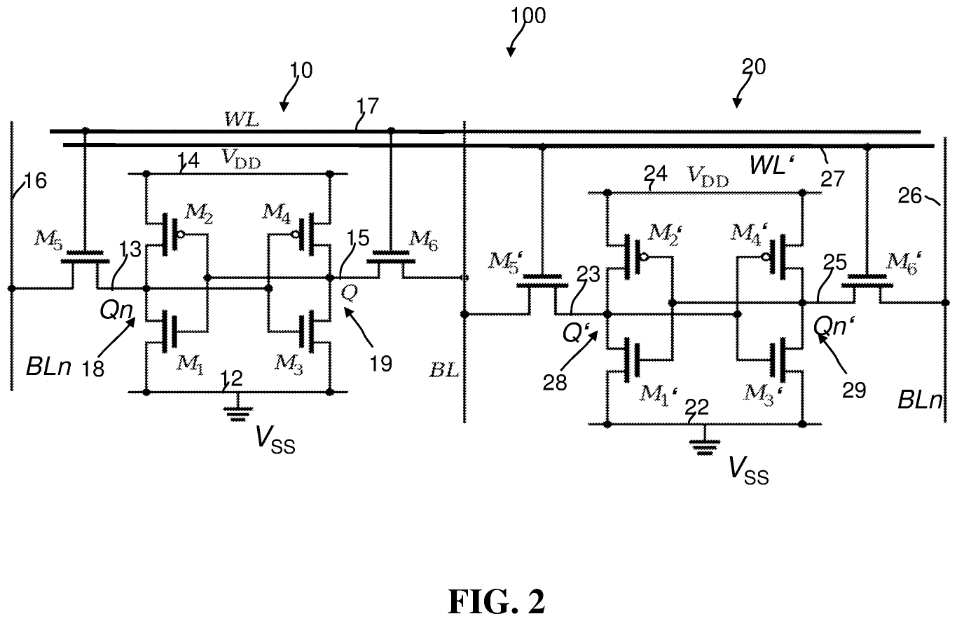

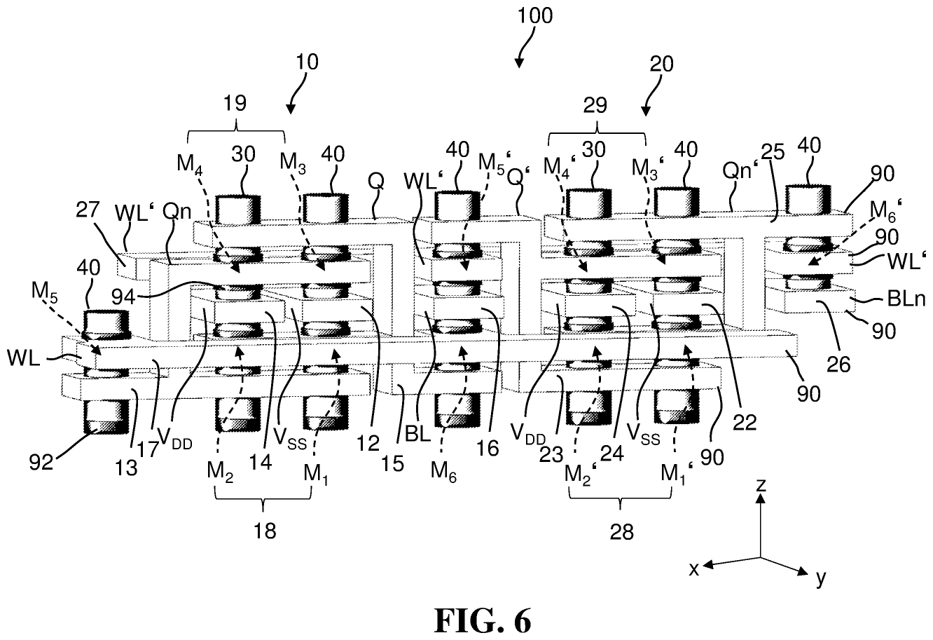

FIG. 2 depicts a circuit diagram of microelectronic device 100 comprising two SRAM memory cells 10, 20 (e.g., first memory cell and second memory cell) with six transistors referred to M₁, M₂, M₃, M₄, M₅, M₆, M₁′, M₂′, M₃′, M₄′, M₅′, M₆′, respectively. Each may share a common true bitline BL according to an embodiment of the invention. The principal structure of the two memory cells 10, 20 is the same as already described with FIG. 1. Nets 12, 13, 14, 15, 16, 17, 22, 23, 24, 25, 26, 27, as depicted in FIG. 1, may correspond to physical structures shown in FIG. 6, depicted for clarification.

The memory cell 20 comprises a first inverter 28 with a first transistor M₁′ and a second transistor M₂′ and a second inverter 29 with a first transistor M₃′ and a second transistor M₄′.

The transistors M₅, M₆ of the even cell 10 (e.g., first memory cell) may be connected to a wordline WL and the transistors M₅′, M₆′ of the odd cell 20 may be connected to a different wordline WL′. A drain of the transistor M₅ may be connected to the complement bitline BLn and a drain of the transistor M₆′ may be connected to another complement bitline BLn.

The two memory cells 10, 20 may be implemented as an even cell (e.g., first memory cell 10) and an odd cell (e.g., second memory cell 20). They may be connected at the common true bitline BL which may be connected to a transistor M₆ of the even cell 10 and to a transistor M₅′ of the odd cell 20. The connection of the two transistors M₅′, M₆ offers the possibility to stack the two memory cells 10, 20 onto each other in a three-dimensional structure of the microelectronic device 100.

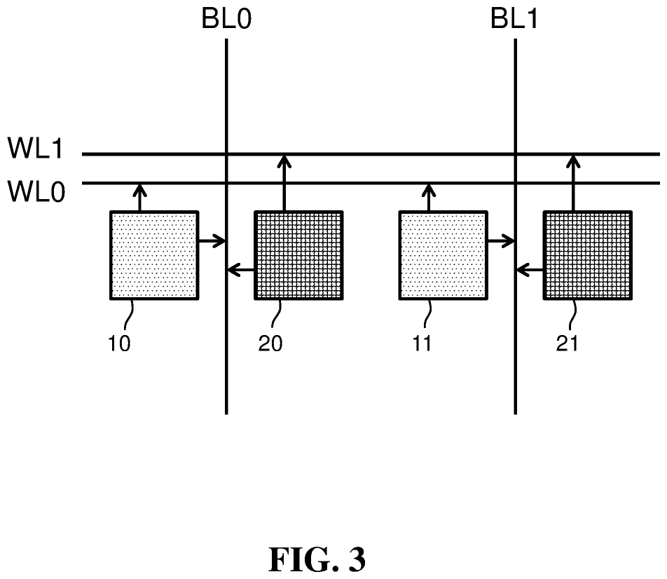

FIG. 3 depicts schematics of memory cells 10, 11, 20, 21 in interleaving two rows sharing bitlines BL0, BL1 and wordlines WL0, WL1 according to an embodiment of the invention.

Advantageously the even memory cells 10, 11 may be connected to a single wordline WL0, whereas the odd memory cells 20, 21 may be connected to another single wordline WL1. The pairs of even and odd memory cells 10, 20 and 11, 21 may share a common bitline, BL0 and BL1 respectively.

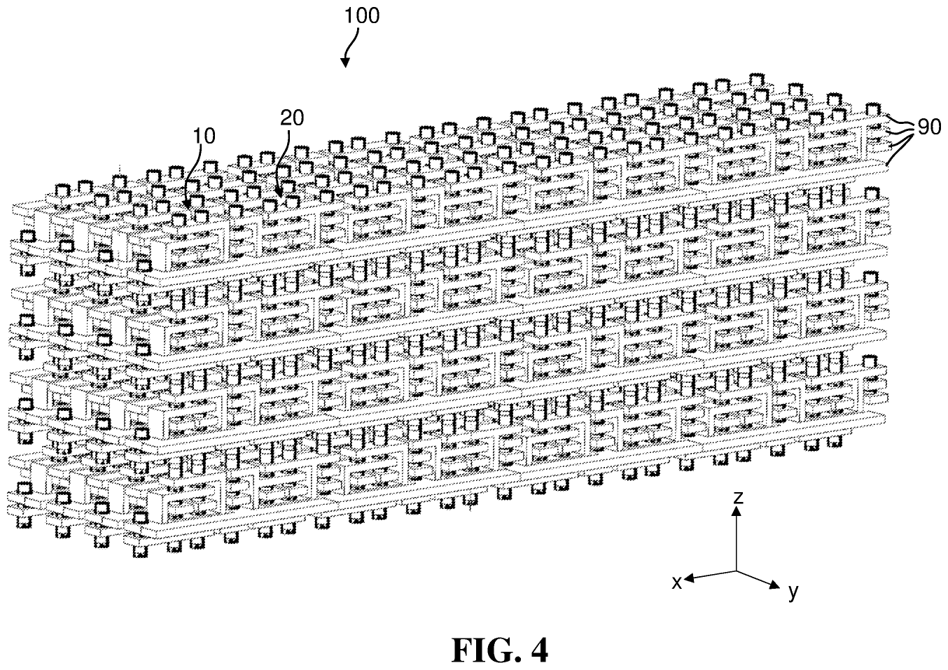

FIG. 4 depicts a physical structure of a microelectronic device 100 comprising three-dimensional stacking of memory cells 10, 20 according to an embodiment of the invention in an isometric view. A coordinate system in x-y-z-direction for the physical structure is defined.

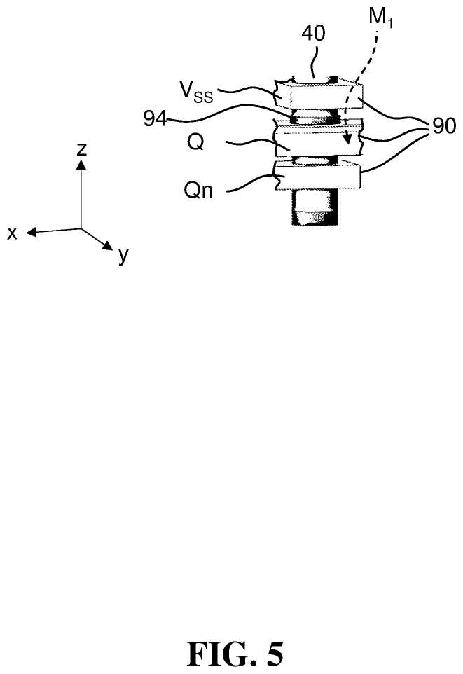

The microelectronic device 100 may be implemented by a plurality of different conducting layers 90, where only the conducting layers 90 of a top layer of memory cells are referenced. Only two adjacent memory cells 10, 20 are marked which will be focused to in the following FIGS. 5 to 10.

FIG. 5 depicts a physical structure of a single transistor M₁ of the microelectronic device 100 according to an embodiment of the invention in an isometric view. This single transistor M₁ may be an example for just one element of the physical structure shown in FIG. 4.

The transistor M₁ may be implemented on a single vertical channel 40 of n-doped silicon. Conducting layers 90 may be wrapped around the vertical channel 40 and connected transverse to the channel 40 of the transistor M₁. The conducting layers 90 comprise a source electrode, that may be connected to a first power line Vₛₛ, a gate electrode 94. The first power line Vₛₛ, a gate electrode 94 may be connected to a true signal Q and a drain electrode. The drain electrode may be connected to a complement signal Qn.

The vertical channel regions may each be covered by a gate dielectric (e.g., a gate oxide). The gate dielectrics may be surrounded by the common gate electrode 94. This is depicted in FIG. 5 with the dark ring circling channel 40.

The channel 40 is depicted as a round column. The round column is often convenient for manufacturing silicon electrodes of a microelectronic device 100.

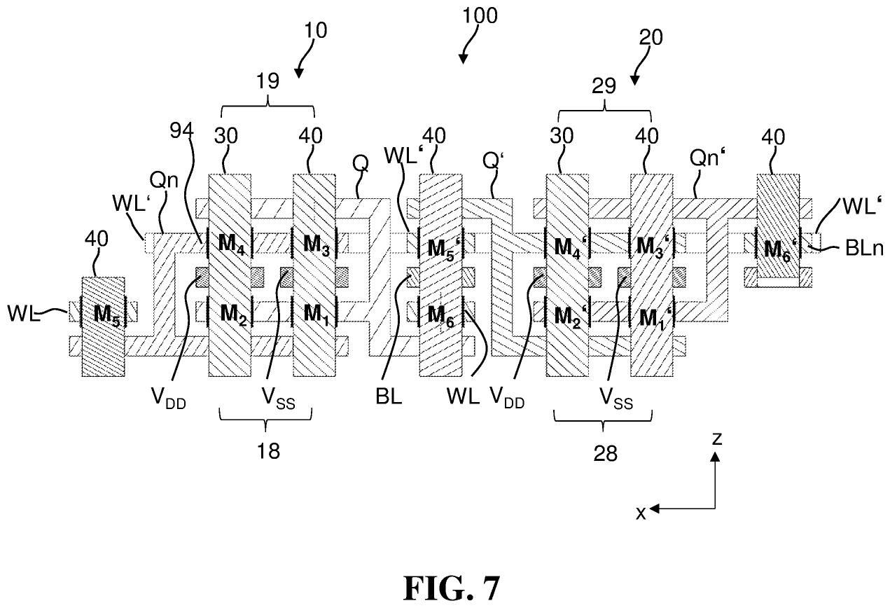

FIG. 6 depicts an isometric view of a physical structure of a microelectronic device 100, such as the physical structure shown in FIG. 4. The isometric view of a physical structure of a microelectronic device 100 may comprise two memory cells 10, 20 with three-dimensional stacking of transistors M₁, M₂, M₃, M₄, M₅, M₆, M₁′, M₂′, M₃′, M₄′, M₅′, M₆′ according to an embodiment of the invention. FIG. 7 depicts a cross section of the microelectronic device 100 according to FIG. 6 in the x-z-plane. The cross section is cut in an x-z-plane at a y-value where the silicon channels 30, 40 of the physical structure are placed.

The net 17 is placed in front of the other parts. In some embodiments, there may be no connection between different nets 12, 13, 14, 15, 16, 17, 22, 23, 24, 25, 26, 27. In some embodiments, the different nets may be all placed apart from each other. In such embodiments, there may be a gap, such as the gap between the net 17 being in front and the net 13 being placed behind.

The silicon channels 30, 40 may exhibit an insulating layer 92, which is exemplarily marked at the left most channel 40, at a lower end of the depicted physical structure in FIG. 6 in order to separate different layers of memory cells 10, 20.

Gate electrodes 94 of the transistors M₁, M₂, M₃, M₄, M₅, M₆, M₁′, M₂′, M₃′, M₄′, M₅′, M₆′ are implemented on the silicon channels 30, 40 by wrapping dielectric layers, (e.g. a gate oxide), between the channels 30, 40 and the conduction nets 13, 15, 17, 23, 27, because the transistors M₁, M₂, M₃, M₄, M₅, M₆, M₁′, M₂′, M₃′, M₄′, M₅′, M₆′ are of a FET type. The gate electrode 94 may be only marked at one transistor M₄ for clarity. In FIG. 7 the gate electrode 94 may correspond to a dark line on both sides of the channels 30, 40.

The microelectronic device 100 may be implemented with a plurality of conducting layers 90, as depicted in FIG. 4. As may be seen in the figure, the conducting layers 90 may be mainly implemented as planar layers, but may also be routed vertically in order to be continued in another layer 90 further down or up. The transistors M₁, M₂, M₃, M₄, M₅, M₆, M₁′, M₂′, M₃′, M₄′, M₅′, M₆′ may also be contacted from different directions in a layer 90, in particular from directions perpendicular to one another.

The microelectronic device 100 further comprises the first memory cell 10 with at least six transistors M₁, M₂, M₃, M₄, M₅, M₆, and the second memory cell 20 with at least six transistors M₁′, M₂′, M₃′, M₄′, M₅′, M₆′.

The first pair of transistors M₁, M₃; M₁′, M₃′ of the first memory cell 10 and the second memory cell 20, respectively, may be stacked vertically and connected at a common net 12, 22. The common nets 12, 22 may be arranged transverse to the first pair of transistors M₁, M₃; M₁′, M₃′. Each transistor M₁, M₁′, M₃, M₃′ of the first pair of transistors M₁, M₃; M₁′, M₃′ may be of the same type (e.g., an N-FET), as they are implemented on the same channel 40 of e.g., n-doped silicon. The transistors M₁, M₃; M₁′, M₃′ of the first pair of transistors M₁, M₃; M₁′, M₃′ may share a first common power line Vₛₛ, implemented as the common net 12, 22, respectively.

The second pair of transistors M₂, M₄; M₂′, M₄′ of the first memory cell 10 and the second memory cell 20, respectively, may be stacked vertically and connected at a common net 14, 24. The common nets 14, 24 are arranged transverse to the second pair of transistors M₂, M₄; M₂′, M₄′. Each transistor M₂, M₂′, M₄, M₄′ of the second pair of transistors M₂, M₄; M₂′, M₄′ may be of the same type, e.g., a P-FET, as they are implemented on the same channel 30 of e.g., p-doped silicon. The transistors M₂, M₂′, M₄, M₄′ of the second pair of transistors M₂, M₄; M₂′, M₄′ may be a different type than the first pair of transistors M₁, M₃; M₁′, M₃′. The transistors M₂, M₄; M₂′, M₄′ of the second pair of transistors M₂, M₄; M₂′, M₄′ share a second common power line V_{dd}, implemented as the common net 14, 24, respectively.

The transistors M₁, M₁′, M₂, M₂′, M₃, M₃′, M₄, M₄′ of the first and second pair of transistors M₁, M₃; M₁′, M₃′; M₂, M₄; M₂′, M₄′ may operate independently from each other.

The third pair of transistors M₅′, M₆ of the first and the second memory cell 10, 20 may be stacked vertically and connected at a common net 16, 26. The common net 16 may be arranged transverse to the third pair of transistors M₅′, M₆. Each transistor M₅′, M₆ of the third pair of transistors M₅′, M₆ may be of the same type, e.g., an N-FET, as they are implemented on the same channel 40 of e.g., n-doped silicon. The transistors M₅′, M₆ of the third pair of transistors M₅′, M₆ share a common true bit line BL, implemented as the common net 16.

As the two memory cells 10, 20 are part of a periodic structure of the microelectronic device 100 the third pair of transistors is in reality continued to either side of the microelectronic device 100 depicted in FIG. 6. That means, that the transistor M₆′ of the second memory cell 20 may be stacked on top of a transistor M₅ of a right hand sided adjacent, but not depicted first memory cell, and the transistor M₅ of the first memory cell 10 may be stacked below a transistor M₆′ of a left hand sided adjacent, but not depicted second memory cell, sharing a common complement bit line BLn, implemented as the common net 26.

Therefore, the transistors M₅′, M₆; M₅, M₆′ of the third pair of transistors M₅′, M₆; M₅, M₆′ of adjacent memory cells 10, 20 may be formed in different layers 90. Besides, the transistors M₅′, M₆; M₅, M₆′ of the third pair of transistors M₅′, M₆; M₅, M₆′ may be connected to different wordlines WL, WL′. The wordlines WL and WL′ may be in different layers.

Thus, the first memory cell 10 and the second memory cell 20 may have at least six transistors M₁, M₂, M₃, M₄, M₅, M₆ and M₁′, M₂′, M₃′, M₄′, M₅′, M₆′ each, forming three stacks of stacked transistors M₁, M₃, M₁′, M₃′; M₂, M₄, M₂′, M₄′; M₅′, M₆, M₅, M₆′ per memory cell 10, 20.

The first transistors M₁, M₁′, M₂, M₂′, M₅, M₅′ of the first pair M₁, M₃; M₁′, M₃′, the second pair M₂, M₄; M₂′, M₄′ and the third pair of transistors M₅′, M₆; M₅, M₆′ share one common net 13, 23 and may be connected to a complement signal Qn in the first memory cell 10 and to a true signal Q′ in the second memory cell 20.

The second transistors M₃, M₃′, M₄, M₄′, M₆, M₆′ of the first pair M₁, M₃; M₁′, M₃′, the second pair M₂, M₄; M₂′, M₄′ and the third pair of transistors M₅′, M₆, M₅, M₆′ may share another net 15, 25 and may be connected to a true signal Q in the first memory cell 10 and to a complement signal Qn′ in the second memory cell 20.

A first inverter 18, 28 as defined in FIG. 2, comprises the first transistor M₁, M₁′ of the first pair of transistors M₁, M₃; M₁′, M₃′ and the first transistor M₂, M₂′ of the second pair of transistors M₂, M₄; M₂′, M₄′. A second inverter 19, 29 comprises the second transistor M₃, M₃′ of the first pair of transistors M₁, M₃; M₁′, M₃′ and the second transistor M₄, M₄′ of the second pair of transistors M₂, M₄; M₂′, M₄′.

The first inverter 18 and the second inverter 19 may be cross coupled.

The first inverter 18 may invert a true signal Q and drives a complement signal Qn, the second inverter 19 inverts a complement signal Qn and drives a true signal Q.

The depicted microelectronic device 100 as depicted in the Figures may be manufactured according to the proposed method of forming a microelectronic device 100 comprising a plurality of conducting layers 90, the method comprising: forming a first power line Vₛₛ; forming a second power line V_{dd}; forming a first memory cell 10 with at least six transistors M₁, M₂, M₃, M₄, M₅, M₆; forming a second memory cell 20 with at least six transistors M₁′, M₃′, M₄′, M₅′, M₆′.

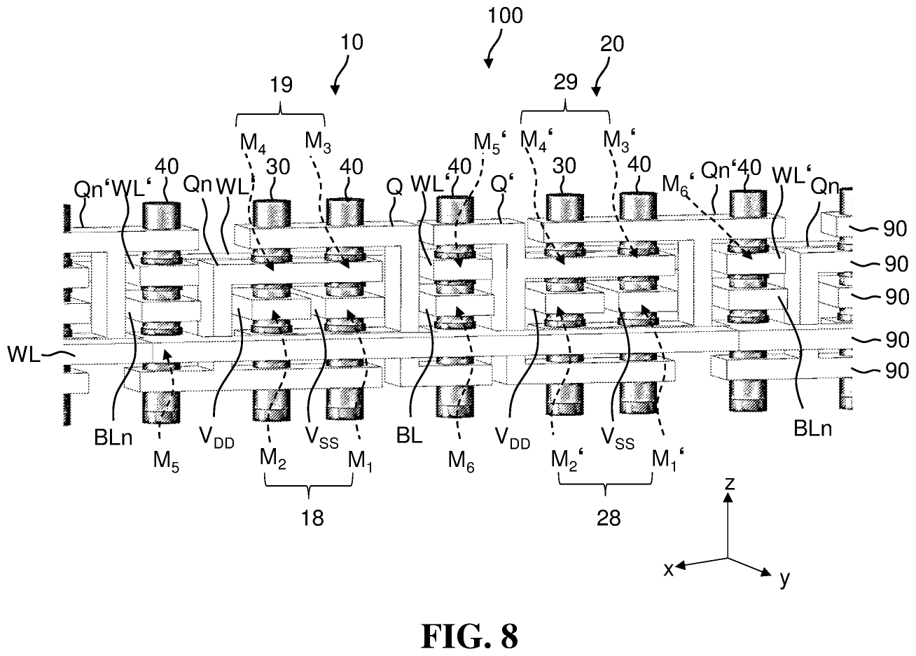

FIG. 8 depicts the microelectronic device 100 with the two memory cells 10, 20 according to FIG. 6 embedded in adjacent memory cells of the physical structure in an isometric view. This may be a concurrent follow up of memory cells 10, 20 in one of the horizontal direction x.

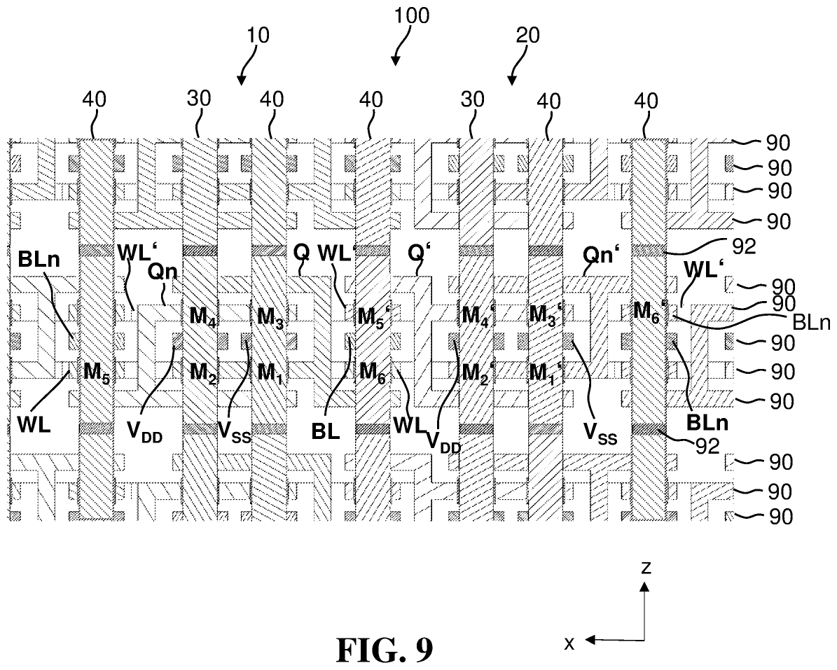

FIG. 9 depicts a cross section of the microelectronic device 100 according to FIG. 8 in the x-z-plane, where a further concurrent follow up of the memory cells 10, 20 can be seen, in a vertical direction z, as depicted in the big physical structure in FIG. 4.

In the embodiments shown in the FIGS. 8 and 9 a number of additional conducting layers 90 are depicted, implementing additional memory cells which are adjacent and connected to the two memory cells 10, 20 described in FIGS. 6 and 7. Thus an integrated circuit comprising a plurality of microelectronic devices 100 with two memory cells 10, 20 may be implemented. Between different layers of memory cells 10, 20 in the z-direction insulating layers 92 are implemented, depicted as dark regions in FIG. 9, interrupting the silicon channels 30, 40 in the z-direction in order to separate different layers of memory cells 10, 20.

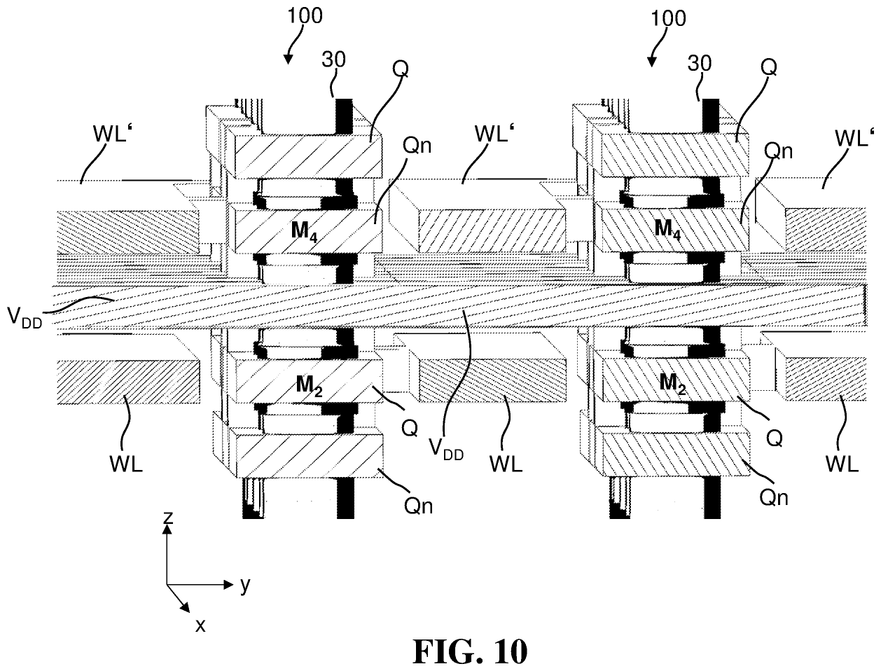

FIG. 10 depicts the physical structure of the microelectronic device 100 comprising two memory cells 10, 20 according to FIG. 8 in an isometric view cut in the y-z-plane.

In this embodiment, the cross section second pairs of transistors M₂, M₄ stacked on channels 30 may be side by side. The pairs of transistors M₂, M₄ may be connected to the second power line V_{dd}. The second power lines V_{dd} may run uninterrupted from side to side in the y-direction. In the cross section, the word lines WL as well as the word lines WL′ may be cut as they are routed in the x-direction perpendicular to the y-z-plane of the FIG. 10.

In x-direction behind the silicon channels 30 with the second pairs of transistors M₂, M₄ silicon channels 40 with first pairs of transistors M₁, M₂ may be placed by an other pair of second transistors in alternated rows.

The described microelectronic device 100 as depicted in the Figures may be manufactured according to the provided method of forming a microelectronic device 100 comprising a plurality of conducting layers 90, the method comprising: a processor forming a first power line V Ss; a processor forming a second power line V dd; a processor forming a first memory cell 10 with at least six transistors M₁, M₂, M₃, M₄, M₅, M₆; a processor forming a second memory cell 20 with at least six transistors M₁′, M₂′, M₃′, M₄′, M₅′, M₆′.

A first pair of transistors M₁, M₃; M₁′, M₃′ of the first memory cell 10 may be stacked vertically and connected at a common net 12, 22, in particular connected at a common net 12, 22 arranged transverse to the first pair of transistors M₁, M₃; M₁′, M₃′. Each transistor M₁, M₁′, M₃, M₃′ of the first pair of transistors M₁, M₃; M₁′, M₃′ may be of the same type, and wherein the first pair of transistors M₁, M₃; M₁′, M₃′ shares the first common power line Vₛₛ.

A second pair of transistors M₂, M₄; M₂′, M₄′ of the first memory cell 10 is stacked vertically and connected at a common net 14, 24, arranged transverse to the second pair of transistors M₂, M₄; M₂′, M₄′. Each transistor M₂, M₂′, M₄, M₄′ of the second pair of transistors M₂, M₄; M₂′, M₄′ may be of the same type, and being a different type than the first pair of transistors M₁, M₃; M₁′, M₃′. The second pair of transistors M₂, M₄; M₂′, M₄′ may share the second common power line V_{dd}.

The transistors M₁, M₁′, M₂, M₂′, M₃, M₃′, M₄, M₄′ of the first and second pair of transistors M₁, M₃; M₁′, M₃′; M₂, M₄; M₂′, M₄′ may be operating independently from each other.

A third pair of transistors M₅′, M₆; M₅, M₆′ of the second and the first memory cell 10 may be stacked vertically and connected at a common net 16, 26, in particular connected at a common net 16, 26 arranged transverse to the third pair of transistors M₅′, M₆; M₅, M₆′. Each transistor M₅, M₅′, M₆, M₆′ of the third pair of transistors M₅′, M₆; M₅, M₆′ is of the same type. The third pair of transistors M₅′, M₆; M₅, M₆′ shares a common bit line BL, BLn.

Standard processes of semiconductor manufacturing may be used, building up layer by layer. Thus, the transistors M₁, M₁′, M₂, M₂′, M₃, M₃′, M₄, M₄′, M₅′, M₆, M₅, M₆′ as well as all the power lines Vₛₛ, V_{DD} and connecting nets 12, 13, 14, 15, 16, 17, 22, 23, 24, 25, 26, 27 may be built in parallel in the x-y-plane of the physical structure of the microelectronic device 100.

Further exemplary embodiments of the present disclosure are set out in the following numbered clauses:

In some embodiments, a microelectronic device 100 comprising a plurality of conducting layers 90. The microelectronic device 100 may comprise a first memory cell 10 with at least six transistors (e.g., M₁, M₂, M₃, M₄, M₅, M₆), a second memory cell 20 with at least six transistors (e.g., M₁′, M₃′, M₄′, M₅′, M₆′). The first pair of transistors (e.g., M₁, M₃; M₁′, M₃′) of the first memory cell 10 may be stacked vertically and connected at a common net 12, 22, arranged transverse to the first pair of transistors (e.g., M₁, M₃; M₁′, M₃′). Each transistor (e.g., M₁, M₁′, M₃, M₃′) of the first pair of transistors (e.g., M₁, M₃; M₁′, M₃′) may be of the same type. The first pair of transistors (e.g., M₁, M₃; M₁′, M₃′) may share a first common power line (Vₛₛ). A second pair of transistors (e.g., M₂, M₄; M₂′, M₄′) of the first memory cell 10 may be stacked vertically and connected at a common net 14, 24, arranged transverse to the second pair of transistors (e.g., M₂, M₄; M₂′, M₄′). Each transistor (e.g., M₂, M₂′, M₄, M₄′) of the second pair of transistors (e.g., M₂, M₄; M₂′, M₄′) is of the same type, and being a different type than the first pair of transistors (e.g., M₁, M₃; M₁′, M₃′), wherein the second pair of transistors (e.g., M₂, M₄; M₂′, M₄′) shares a second common power line (V_{dd}), wherein the transistors (e.g., M₁, M₁′, M₂, M₂′, M₃, M₃′, M₄, M₄′) of the first and second pair of transistors (e.g., M₁, M₃; M₁′, M₃′; M₂, M₄; M₂′, M₄′) are operating independently from each other.

In some embodiments, the microelectronic device may include a third pair of transistors (e.g., M₅′, M₆; M₅, M₆′) of the first and the second memory cell 10, 20 may be stacked vertically and connected at a common net 16, 26, arranged transverse to the third pair of transistors (e.g., M₅′, M₆; M₅, M₆′). Each transistor (e.g., M₅, M₅′, M₆, M₆′) of the third pair of transistors (e.g., M₅′, M₆; M₅, M₆′) may be of the same type. The third pair of transistors (e.g., M₅′, M₆; M₅, M₆′) may share a common bit line (e.g., BL and/or BLn).

In some embodiments, the microelectronic device may further include first memory cell 10 and the second memory cell 20. The memory cell 10 and the second memory cell 20 may each have at least six transistors (e.g., M₁, M₂, M₃, M₄, M₅, M₆) and (e.g., M₁′, M₂′, M₃′, M₄′, M₅′, M₆′). In some embodiments, three stacks of stacked transistors (e.g., M₁, M₃, M₁′, M₃′; M₂, M₄, M₂′, M₄′; M₅′, M₆, M₅, M₆′) may be formed in each memory cell 10, 20.

In some embodiments, the microelectronic device may further include a first inverter 18, 28 comprises a first transistor (e.g., M₁, M₁′) of the first pair of transistors (e.g., M₁, M₃; M₁′, M₃′) and a first transistor (e.g., M₂, M₂′) of the second pair of transistors (e.g., M₂, M₄; M₂′, M₄′). In some embodiments, a second inverter 19, 29 may comprise a second transistor (e.g., M₃, M₃′) of the first pair of transistors (e.g., M₁, M₃; M₁′, M₃′) and a second transistor (e.g., M₄, M₄′) of the second pair of transistors (e.g., M₂, M₄; M₂′, M₄′).

In some embodiments, the microelectronic device may further include the first inverter 18, 28 cross coupled to the second inverter 19, 29.

In some embodiments, the microelectronic device may further include the first inverter 18, 28 inverting a true signal (e.g., Q) and driving a complement signal (e.g., Qn). The second inverter 19, 29 may invert a complement signal (e.g., Qn) and drive a true signal (e.g., Q).

In some embodiments, the third pair of transistors (e.g., M₅′, M₆; M₅, M₆′) may be connected to a true bitline (e.g., BL) or to a complement bitline (e.g., BLn).

In some embodiments, the microelectronic device may further include the first transistors (e.g., M₁, M₁′, M₂, M₂′, M₅, M₅′) of the first pair (e.g., M₁, M₃; M₁′, M₃′), the second pair (e.g., M₂, M₄; M₂′, M₄′) and the third pair of transistors (e.g., M₅′, M₆; M₅, M₆′) share one net and are connected to a complement signal (e.g., Qn) in the first memory cell 10 and to a true signal (e.g., Q′) in the second memory cell 20, wherein the second transistors (e.g., M₃, M₃′, M₄, M₄′, M₆, M₆′) of the first pair (e.g., M₁, M₃; M₁′, M₃′), the second pair (e.g., M₂, M₄; M₂′, M₄′) and the third pair of transistors (e.g., M₅′, M₆; M₅, M₆′) share another net and are connected to a true signal (e.g., Q) in the first memory cell 10 and to a complement signal (e.g., Qn′) in the second memory cell 20.

In some embodiments, the transistors (e.g., M₅′, M₆; M₅, M₆′) of the third pair of transistors (e.g., M₅′, M₆; M₅, M₆′) of adjacent memory cells 10, 20 may be formed in different layers 90.

In some embodiments, the transistors (e.g., M₅′, M₆; M₅, M₆′) of the third pair of transistors (e.g., M₅′, M₆; M₅, M₆′) may be connected to different wordlines (e.g., WL, WL′).

In some embodiments, the microelectronic device may include a plurality of conducting layers (90). A method of forming a microelectronic device may include: forming a first power line (e.g., Vₛₛ); forming a second power line (e.g., V_{dd}); forming a first memory cell 10 with at least six transistors (e.g., M₁, M₂, M₃, M₄, M₅, M₆); forming a second memory cell 20 with at least six transistors (e.g., M₁′, M₂′, M₃′, M₄′, M₅′, M₆′). A first pair of transistors (e.g., M₁, M₃; M₁′, M₃′) of the first memory cell 10 may be stacked vertically and connected at a common net 12, 22, arranged transverse to the first pair of transistors (e.g., M₁, M₃; M₁′, M₃′). Each transistor (e.g., M₁, M₁′, M₃, M₃′) of the first pair of transistors (e.g., M₁, M₃; M₁′, M₃′) may be of the same type. The first pair of transistors (e.g., M₁, M₃; M₁′, M₃′) may share the first common power line (e.g., Vₛₛ). A second pair of transistors (e.g., M₂, M₄; M₂′, M₄′) of the first memory cell 10 may be stacked vertically and connected at a common net 14, 24, arranged transverse to the second pair of transistors (e.g., M₂, M₄; M₂′, M₄′). Each transistor (e.g., M₂, M₂′, M₄, M₄′) of the second pair of transistors (e.g., M₂, M₄; M₂′, M₄′) may be of the same type and may be a different type than the first pair of transistors (e.g., M₁, M₃; M₁′, M₃′). The second pair of transistors (e.g., M₂, M₄; M₂′, M₄′) may share the second common power line (e.g., V_{dd}). The transistors (e.g., M₁, M₁′, M₂, M₂′, M₃, M₃′, M₄, M₄′) of the first and second pair of transistors (e.g., M₁, M₃; M₁′, M₃′; M₂, M₄; M₂′, M₄′) may operate independently from each other.

In some embodiments, the microelectronic device may include a third pair of transistors (e.g., M₅′, M₆; M₅, M₆′) associated with the second and the first memory cell 10 may be stacked vertically and connected at a common net 16, 26, arranged transverse to the third pair of transistors (e.g., M₅′, M₆; M₅, M₆′). Each transistor (e.g., M₅, M₅′, M₆, M₆′) of the third pair of transistors (e.g., M₅′, M₆; M₅, M₆′) is of the same type. The third pair of transistors (e.g., M₅′, M₆; M₅, M₆′) may share a common bit line (e.g., BL, BLn).

In some embodiments, the microelectronic device may include a second memory cell 20 having at least six transistors (e.g., M₁, M₂, M₃, M₄, M₅, M₆) and (e.g., M₁′, M₂′, M₃′, M₄′, M₅′, M₆′). Each of the at least six transistors may form three stacks of stacked transistors (e.g., M₁, M₃, M₁′, M₃′; M₂, M₄, M₂′, M₄′; M₅′, M₆) for each memory cell 10, 20.

In some embodiments, the microelectronic device may include a first inverter 18, 28. The first inverter 18, 28 may include a first transistor (e.g., M₁, M₁′) of the first pair of transistors (e.g., M₁, M₃; M₁′, M₃′) and a first transistor (e.g., M₂, M₂′) of the second pair of transistors (e.g., M₂, M₄; M₂′, M₄′). A second inverter 19, 29 may be formed comprising a second transistor (e.g., M₃, M₃′) of the first pair of transistors (e.g., M₁, M₃; M₁′, M₃′) and a second transistor (e.g., M₄, M₄′) of the second pair of transistors (e.g., M₂, M₄; M₂′, M₄′).

In some embodiments, the microelectronic device may have the first inverter 18, 28 cross coupled to the second inverter 19, 29.

In some embodiments, the microelectronic device may include the first inverter 18, 28. The first inverter may invert a true signal (e.g., Q) and drives a complement signal (e.g., Qn). The second inverter 19, 29 may be formed by inverting a complement signal (e.g., Qn) and driving a true signal (e.g., Q).

In some embodiments, the microelectronic device may include a third pair of transistors (e.g., M₅′, M₆; M₅, M₆′) that may be connected to a true bitline (e.g., BL) or to a complement bitline (e.g., BLn).

In some embodiments, the microelectronic device may include the first transistors (e.g., M₁, M₁′, M₂, M₂′, M₅, M₅′) of the first pair (e.g., M₁, M₃; M₁′, M₃′), the second pair (e.g., M₂, M₄; M₂′, M₄′), and the third pair of transistors (e.g., M₅′, M₆; M₅, M₆′). The first pair, second pair, and third pair of transistors may be formed by sharing one net and may be connected to a complement signal (e.g., Qn) in the first memory cell 10 and to a true signal (e.g., Q′) in the second memory cell 20. The second transistors (e.g., M₃, M₃′, M₄, M₄′, M₆, M₆′) of the first pair (e.g., M₁, M₃; M₁′, M₃′) and the second pair (e.g., M₂, M₄; M₂′, M₄′) and the third pair of transistors (e.g., M₅′, M₆; M₅, M₆′) may be formed by sharing another net and may be connected to true signal (e.g., Q) in the first memory cell 10 and to a complement signal (e.g., Qn′) in the second memory cell 20.

In some embodiments, the microelectronic device may include transistors (e.g., M₅, M₅′, M₆, M₆′) of the third pair of transistors (e.g., M₅′, M₆; M₅, M₆′) of adjacent memory cells 10, 20 may be formed in different layers 90.

In some embodiments, the microelectronic device may include transistors (e.g., M₅, M₅′, M₆, M₆′) of the third pair of transistors (e.g., M₅′, M₆; M₅, M₆′) that may be connected to different wordlines (e.g., WL, WL′).

In an alternative embodiment, the microelectronic device may include a first memory cell 10 with at least six transistors (e.g., M₁, M₂, M₃, M₄, M₅, M₆) and a second memory cell 20 with at least six transistors (e.g., M₁′, M₂′, M₃′, M₄′, M₅′, M₆′). In some embodiments, a first pair of transistors (e.g., M₁, M₃; M₁′, M₃′) of the first memory cell 10 may be stacked vertically and connected at a common net 12, 22, arranged transverse to the first pair of transistors (e.g., M₁, M₃; M₁′, M₃′). Each transistor (e.g., M₁, M₁′, M₃, M₃′) of the first pair of transistors (e.g., M₁, M₃; M₁′, M₃′) may be of the same type. In some embodiments, the first pair of transistors (e.g., M₁, M₃; M₁′, M₃′) may share a first common power line (e.g., Vₛₛ). A second pair of transistors (e.g., M₂, M₄; M₂′, M₄′) of the first memory cell 10 may be stacked vertically and connected at a common net 14, 24, arranged transverse to the second pair of transistors (e.g., M₂, M₄; M₂′, M₄′). Each transistor (e.g., M₂, M₂′, M₄, M₄′) of the second pair of transistors (e.g., M₂, M₄; M₂′, M₄′) may be of the same type, and may be a different type than the first pair of transistors (e.g., M₁, M₃; M₁′, M₃′). The second pair of transistors (e.g., M₂, M₄; M₂′, M₄′) may share a second common power line (V_{dd}). The transistors (e.g., M₁, M₁′, M₂, M₂′, M₃, M₃′, M₄, M₄′) of the first and second pair of transistors (e.g., M₁, M₃; M₁′, M₃′; M₂, M₄; M₂′, M₄′) may be operated independently from each other. A third pair of transistors (e.g., M₅′, M₆; M₅, M₆′) of the first and the second memory cell 10, 20 may be stacked vertically and connected at a common net 16, 26, arranged transverse to the third pair of transistors (e.g., M₅′, M₆; M₅, M₆′). Each transistor (e.g., M₅, M₅′, M₆, M₆′) of the third pair of transistors (e.g., M₅′, M₆; M₅, M₆′) may be of the same type. In some embodiments, the third pair of transistors (e.g., M₅′, M₆; M₅, M₆′) may share a common bit line (e.g., BL, BLn).

In some embodiments, the microelectronic device may include forming a first power line (e.g., Vₛₛ), forming a second power line (e.g., V_{dd}), forming a first memory cell 10 with at least six transistors (e.g., M₁, M₂, M₃, M₄, M₅, M₆), and forming a second memory cell 20 with at least six transistors (e.g., M₁′, M₂′, M₃′, M₄′, M₅′, M₆′). In some embodiments, a first pair of transistors (e.g., M₁, M₃; M₁′, M₃′) of the first memory cell 10 may be stacked vertically and connected at a common net 12, 22, arranged transverse to the first pair of transistors (e.g., M₁, M₃; M₁′, M₃′). Each transistor (e.g., M₁, M₁′, M₃, M₃′) of the first pair of transistors (e.g., M₁, M₃; M₁′, M₃′) may be of the same type of transistor. The first pair of transistors (e.g., M₁, M₃; M₁′, M₃′) may share the first common power line (e.g., Vₛₛ). A second pair of transistors (e.g., M₂, M₄; M₂′, M₄′) of the first memory cell 10 may be stacked vertically and connected at a common net 14, 24, arranged transverse to the second pair of transistors (e.g., M₂, M₄; M₂′, M₄′). In some embodiments, each transistor (e.g., M₂, M₂′, M₄, M₄′) of the second pair of transistors (e.g., M₂, M₄; M₂′, M₄′) may be of the same type, and may be a different type than the first pair of transistors (e.g., M₁, M₃; M₁′, M₃′). The second pair of transistors (e.g., M₂, M₄; M₂′, M₄′) may share the second common power line (e.g., V_{dd}). The transistors (e.g., M₁, M₁′, M₂, M₂′, M₃, M₃′, M₄, M₄′) of the first and second pair of transistors (e.g., M₁, M₃; M₁′, M₃′; M₂, M₄; M₂′, M₄′) may be operated independently from each other. A third pair of transistors (e.g., M₅′, M₆; M₅, M₆′) of the second and the first memory cell 10 may be stacked vertically and connected at a common net 16, 26, 26 arranged transverse to the third pair of transistors (e.g., M₅′, M₆; M₅, M₆′). In some embodiments, each transistor (e.g., M₅, M₅′, M₆, M₆′) of the third pair of transistors (e.g., M₅′, M₆; M₅, M₆′) may be of the same type. The third pair of transistors (e.g., M₅′, M₆; M₅, M₆′) may share a common bit line (e.g., BL, BLn).

In some embodiments, a computer program product for designing a microelectronic device 100 may include a plurality of conducting layers 90. In some embodiments, the computer program product may include a computer readable storage medium having program instructions embodied therewith the program instructions executable by the computer system 212 to cause the computer system 212 to perform a method. In some embodiments, a processor may design a first power line (e.g., Vₛₛ), design a second power line (e.g., V_{dd}), design a first memory cell 10 with at least six transistors (e.g., M₁, M₂, M₃, M₄, M₅, M₆), design a second memory cell 20 with at least six transistors (e.g., M₁′, M₂′, M₃′, M₄′, M₅′, M₆′). In some embodiments, a first pair of transistors (e.g., M₁, M₃; M₁′, M₃′) of the first memory cell 10 may be stacked vertically and connected at a common net 12, 22, arranged transverse to the first pair of transistors (e.g., M₁, M₃; M₁′, M₃′). In some embodiments, each transistor (e.g., M₁, M₁′, M₃, M₃′) of the first pair of transistors (e.g., M₁, M₃; M₁′, M₃′) may be of the same type.

The first pair of transistors (e.g., M₁, M₃; M₁′, M₃′) may share the first common power line (e.g., Vₛₛ). In some embodiments, a second pair of transistors (e.g., M₂, M₄; M₂′, M₄′) of the first memory cell 10 may be stacked vertically and connected at a common net 14, 24, arranged transverse to the second pair of transistors (e.g., M₂, M₄; M₂′, M₄′). Each transistor (e.g., M₂, M₂′, M₄, M₄′) of the second pair of transistors (e.g., M₂, M₄; M₂′, M₄′) may be of the same type, and may be a different type than the first pair of transistors (e.g., M₁, M₃; M₁′, M₃′). The second pair of transistors (e.g., M₂, M₄; M₂′, M₄′) may share the second common power line (e.g., V_{dd}), In some embodiments, the transistors (e.g., M₁, M₁′, M₂, M₂′, M₃, M₃′, M₄, M₄′) of the first and second pair of transistors (e.g., M₁, M₃; M₁′, M₃′; M₂, M₄; M₂′, M₄′) may operate independently from each other. A third pair of transistors (e.g., M₅′, M₆; M₅, M₆′) of the second and the first memory cell 10 is stacked vertically and connected at a common net 16, 26, arranged transverse to the third pair of transistors (e.g., M₅′, M₆; M₅, M₆′). In some embodiments, each transistor (e.g., M₅, M₅′, M₆, M₆′) of the third pair of transistors (e.g., M₅′, M₆; M₅, M₆′) may be of the same type, wherein the third pair of transistors (e.g., M₅′, M₆; M₅, M₆′) may share a common bit line (e.g., BL, BLn).

1. A microelectronic device comprising a plurality of conducting layers, the microelectronic device comprising:
a first memory cell with at least six transistors;
a second memory cell with at least six transistors, wherein a first pair of transistors of the first memory cell is stacked vertically and connected at a common net, arranged transverse to the first pair of transistors, wherein the first pair of transistors shares a first common power line; and
a second pair of transistors of the first memory cell, stacked vertically and connected at a common net arranged transverse to the second pair of transistors, wherein the second pair of transistors shares a second common power line, and wherein the transistors of the first pair of transistors and the second pair of transistors operate independently from each other.

2. The microelectronic device according to claim 1, wherein a third pair of transistors of the first and the second memory cell are stacked vertically and connected at a common net arranged transverse to the third pair of transistors, wherein the third pair of transistors shares a common bit line.

3. The microelectronic device according to claim 2, wherein the first memory cell and the second memory cell have at least six transistors and each, wherein the at least six transistors are configured to form three stacks of stacked transistors in each the first memory cell and the second memory cell.

4. The microelectronic device according to claim 1, wherein a first inverter includes a first transistor of the first pair of transistors and a first transistor of the second pair of transistors, wherein a second inverter includes a second transistor of the first pair of transistors and a second transistor of the second pair of transistors.

5. The microelectronic device according to claim 4, wherein the first inverter and the second inverter are cross coupled.

6. The microelectronic device according to claim 4, wherein the first inverter is configured to invert a true signal and to drive a complement signal, and wherein the second inverter is configured to invert a complement signal and to drive a true signal.

7. The microelectronic device according to claim 2, wherein the third pair of transistors is connected to a bitline.

8. The microelectronic device according to claim 2, wherein the first transistors of the first pair the second pair and the third pair of transistors are connected to a complement signal associated with the first memory cell and to a true signal associated with the second memory cell, wherein the second transistors of the first pair of transistors, the second pair of transistors, and the third pair of transistors are connected to a true signal associated with the first memory cell and to a complement signal associated with the second memory cell.

9. The microelectronic device according to claim 2, wherein each of the transistors of the third pair of transistors of adjacent memory cells are formed in different layers.

10. The microelectronic device according to claim 2, wherein the each of the transistors of the third pair of transistors are connected to a different wordline.

11. A method of forming a microelectronic device with a plurality of conducting layers, the method comprising:
forming a first power line;
forming a second power line;
forming a first memory cell with at least six transistors; and
forming a second memory cell with at least six transistors; wherein a first pair of transistors of the first memory cell is stacked vertically and connected at a common net, arranged transverse to the first pair of transistors, wherein the first pair of transistors are configured to share the first power line, wherein a second pair of transistors of the first memory cell are stacked vertically and connected at a common net, arranged transverse to the second pair of transistors; wherein the second pair of transistors are configured to share the second power line, and wherein the transistors of the first pair of transistors are configured to operate independently from the second pair of transistors.

12. The method according to claim 11, further comprising:
connecting a third pair of transistors of the second memory cell and the first memory cell to a common net, wherein the common net is arranged transverse to the third pair of transistors; and
coupling the third pair of transistors to a common bit line.

13. The method according to claim 12, further comprising:
forming three stacks of stacked transistors in each the first memory cell and the second memory cell.

14. The method according to claim 11, further comprising:
forming a first inverter, wherein the first inverter includes a first transistor of the first pair of transistors and a first transistor of the second pair of transistors; and
forming a second inverter, wherein the second inverter includes a second transistor of the first pair of transistors and a second transistor of the second pair of transistors.

15. The method according to claim 14, further including:
cross coupling the first inverter and the second inverter.

16. The method according to claim 14, further including:
forming the first inverter, wherein the first inverter is configured to invert a true signal and to drive a complement signal; and
forming the second inverter wherein the second inverter is configured to invert a complement signal and to drive a true signal.

17. The method according to claim 12, further including:
connecting the third pair of transistors to a bitline.

18. The method according to claim 12, further including:
forming the first transistors of the first pair of transistors, the first transistors of the second pair of transistors, and the first transistors of the third pair of transistors to share one net;
forming the second transistors of the first pair of transistors, the second transistors of the second pair of transistors, and the second transistors of the third pair of transistors to share an other net; and
connecting a complement signal associated with the first memory cell to a true signal in the second memory cell, wherein the second transistors of the first pair of transistors, second transistors of the second pair of transistors and the second transistors of the third pair of transistors are connected to a true signal associated with the first memory cell and to a complement signal associated with the second memory cell.

19. The method according to claim 12, further including:
forming the transistors of the third pair of transistors of adjacent memory cells in different layers.

20. The method according to claim 12, further including:
connecting the transistors of the third pair of transistors to different wordlines.
